(19) United States
(12) Patent Application Publication
(10) Pub. No.: US 2011/0167317 A1
(43) Pub. Date: Jul. 7, 2011

(54) APPARATUS FOR ADAPTABLE/VARIABLE TYPE MODULATION AND DEMODULATION IN DIGITAL TX/RX SYSTEM

(76) Inventors: Sung-Hoon Kim, Daejeon (KR); Eung Don Lee, Daejeon (KR); Jin Soo Choi, Daejeon (KR); Jin Woo Hong, Daejeon (KR); Chung Hyun Ahn, Daejeon (KR); Chang-Joong Kim, Seoul (KR); Kyoung-Hweon Lee, Seoul (KR); Ho-Kyoung Lee, Gyeonggi-do (KR)

(21) Appl. No.: 12/999,539

(22) PCT Filed: Jun. 16, 2009
(86) PCT No.: PCT/KR09/03198

§ 371 Date: Mar. 16, 2011

Related U.S. Application Data
(60) Provisional application No. 61/061,709, filed on Jun. 16, 2008.
(60) Provisional application No. 61/076,735, filed on Jun. 30, 2008.

(30) Foreign Application Priority Data
Apr. 7, 2009 (KR) 10-2009-0029793
Jun. 12, 2009 (KR) 10-2009-0052207

(51) Int. Cl. H03M 13/09

(52) U.S. Cl. 714/758; 714/E11.03

(57) ABSTRACT

Disclosed is an adaptable/variable type modulation/demodulation apparatus. A physical layer transmission apparatus for adaptable/variable type modulation, the transmission apparatus including a classification unit to classify a bit stream according to a standard that is determined in advance after receiving the bit stream, an uncoded bit group unit to group the bit stream not to be LDPC-coded by a predetermined number of bits, an LDPC encoder to perform LDPC-coding of the bit stream, a coded bit group unit to group the coded bit stream by the predetermined number of bits, a quadrature amplitude modulation (QAM) unit to select a symbol coset using the coded bit groups; and a convolutional interleaver to perform convolutional interleaving of the symbol.

### TECHNICAL FIELD

The present invention relates to an adaptable/variable type modulation and demodulation apparatus, and more particularly, to an adaptable/variable type modulation and demodulation apparatus in a transmission/reception system that applies a forward error correction (FEC) scheme to an application layer and uses a low density parity check (LDPC) error correction scheme on partial data in a physical layer, to perform modulation and demodulation.

### BACKGROUND ART

Currently used digital cable transmission systems include a US-based digital cable transmission system, namely DOCSIS/OpenCable, that is based on single carrier 64/256-quadrature amplitude modulation (QAM) type modulation/demodulation using a Reed-Solomon/trellis coded modulation (RS/TCM) error correction code, and also a European-based digital cable transmission system, namely digital video broadcasting-cable (DVB-C), that is based on a 64/256-QAM type modulation/demodulation using an RS error correction code.

However, new transmission standards for next generation broadcasting, such as a low density parity check (LDPC) error correction code and the like, offer a 30 percent increase in a data transmission amount while in an additive white Gaussian noise (AWGN) environment compared with a conventional method.

Accordingly, a 1024/4096-QAM modulation/demodulation scheme which is considered high-dimensional when compared with a 64/256-QAM type modulation/demodulation scheme used in the conventional transmission method has been proposed. However, distortion of a received signal due to a fading channel environment is still a problem preventing wide-spread use of the high-dimensional modulation/demodulation scheme.

Also, a main requirement of the next generation transmission system is that application of a constellation/forward error correction (FEC) variable coding rate in an RF physical layer based on a channel status is applied to a transmission system of each medium.

However, a solution for the problem which introduces an adaptable type modulation/demodulation in an RF physical layer has a low flexibility.

Accordingly, a method of introducing an error correction code in an application layer that has a high flexibility and is advantageous in embodiment/cost is required.

### DISCLOSURE OF INVENTION

### Technical Goals

An aspect of the present invention provides an adaptable/variable type modulation/demodulation apparatus in a digital transmission/reception system.

Another aspect of the present invention also provides an adaptable/variable type modulation/demodulation apparatus in a digital transmission/reception system where a forward error correction (FEC) scheme is applied to an application layer.

Another aspect of the present invention also provides an adaptable/variable type modulation/demodulation apparatus in a digital transmission/reception system where the digital transmission/reception system performs modulation/demodulation of data, and the data determines a coset in a physical layer using LEPC.

Another aspect of the present invention also provides an adaptable/variable type modulation/demodulation apparatus in a digital transmission/reception system that applies an FEC scheme to an application layer and performs modulation/demodulation of partial data in a physical layer using LDPC.

### Technical Solutions

According to an aspect of an exemplary embodiment, there is provided a physical layer transmission apparatus for adaptable/variable type modulation, the transmission apparatus including a classification unit to classify a bit stream into a bit stream to be low density parity check (LDPC)-coded and a bit stream not to be LDPC-coded according to a predetermined scheme, when receiving the bit stream, an uncoded bit group unit to group the bit stream not to be LDPC-coded by a predetermined number of bits to output the uncoded bit groups, an LDPC encoder to perform LDPC-coding of the bit stream to be LDPC-coded to output the coded bit stream, a coded bit group unit to group the coded bit stream by the predetermined number of bits to output the coded bit groups, a quadrature amplitude modulation (QAM) unit to select a symbol coset by using the coded bit groups and to determine a symbol from the selected symbol coset by using the uncoded bit groups, and a convolutional interleaver to perform convolutional interleaving of the symbol determined by the quadrature amplitude modulation unit.

According to another aspect of an exemplary embodiment, there is provided a physical layer reception apparatus for adaptable/variable type demodulation, the reception apparatus including a convolutional deinterleaver to output a soft decision uncoded bit group and a soft decision coded bit group by convolutional deinterleaving a received signal, an LDPC decoder to perform LDPC-decoding of the soft decision coded bit group to output a decoded bit group, an LDPC encoder to perform LDPC-coding of the decoded bit group to output a coded bit group, a symbol coset search unit to select a symbol coset by using the coded bit group, a symbol search unit to select a symbol from the selected symbol coset that the symbol coset search unit selects, by using the soft decision uncoded bit group, an uncoded bit extracting unit to extract an uncoded bit group from the symbol selected through the symbol search unit, and a bit combining unit to combine the decoded bit group and the uncoded bit group to generate a bit stream.

According to another aspect of an exemplary embodiment, there is provided an application layer transmission apparatus, the transmission apparatus including a forward error correction (FEC) code inserting unit to insert, to received robust data, an FEC code for error correction, an error detection code inserting unit to insert, to the robust data where the FEC code is inserted, an error detection code to detect whether the error exists, and a frame multiplexing unit to receive and multiplex normal data and the robust data where the FEC code and the error detection code are inserted and to output the multiplexed data to a physical layer.

According to another aspect of an exemplary embodiment, there is provided a application layer reception apparatus, the reception apparatus including a frame demultiplexing unit to output data by classifying a normal data and robust data when receiving a data stream from a physical layer, an error detecting unit to detect whether an error exists by checking an error detection code included in the robust, and an error correction unit to correct an error by checking an FEC code included in the robust data, when the error detected by the error detecting unit.

### Advantageous Effect

The present invention relates to an adaptable/variable type modulation/demodulation apparatus in a cable transmission/reception system that applies an FEC scheme to an application layer and performs modulation/demodulation of data that determines coset in a physical layer, using an LDPC scheme. The modulation/demodulation is performed using the LDPC scheme only on the data that determines the coset, thereby providing adaptable and variable modulation/demodulation. Also, the error correction is possible based on the LDPC scheme, thereby enabling a large amount of information to be transmitted in a limited bandwidth and increasing a transmission rate. Also, an efficiency of channel equalization occurring in a high-dimensional modulation/demodulation is improved using a training sequence.

### BRIEF DESCRIPTION OF DRAWINGS

FIG. 1 is a diagram illustrating a configuration of an application layer transmission apparatus for forward error correction (FEC) coding according to an embodiment of the present invention;

FIG. 2 is a diagram illustrating a configuration of an application layer reception apparatus for FEC decoding according to an embodiment of the present invention;

FIG. 3 is a diagram illustrating a configuration of a physical layer transmission apparatus including an adaptable/variable type modulation apparatus according to an embodiment of the present invention;

FIG. 4 is a diagram illustrating a configuration of a physical layer reception apparatus including an adaptable/variable type demodulation apparatus according to an embodiment of the present invention; and

FIG. 5 is a diagram illustrating another configuration of an application layer transmission apparatus for FEC coding according to an embodiment of the present invention.

### BEST MODE FOR CARRYING OUT THE INVENTION

Although a few exemplary embodiments of the present invention have been shown and described, the present invention is not limited to the described exemplary embodiments, wherein like reference numerals refer to the like elements throughout.

The present invention relates to an adaptable/variable type modulation/demodulation apparatus in a digital transmission/reception system that applies a forward error correction (FEC) scheme to an application layer and performs modulation/demodulation of data that determines a coset in a physical layer using a low density parity check (LDPC) code/scheme. In this instance, examples of the digital transmission/reception system include a digital cable transmission/reception system, a digital multimedia broadcasting (DMB) system, a satellite DMB system, and an Internet Protocol television (IPTV) system, and the like.

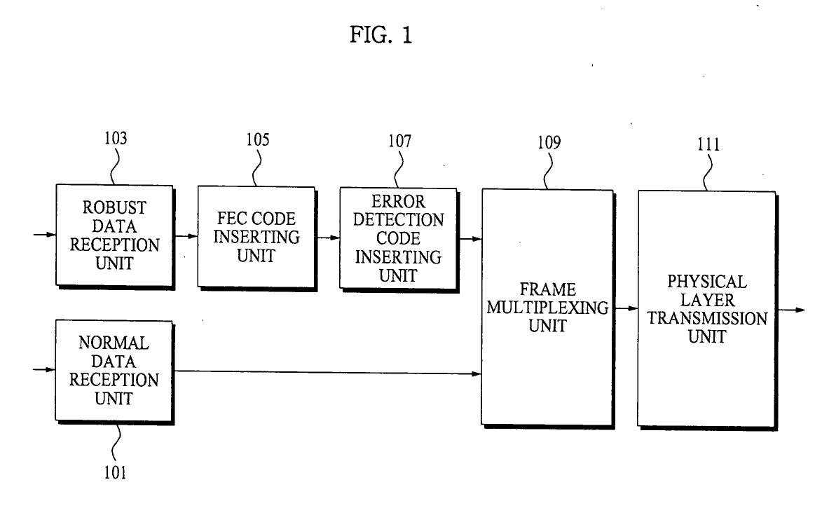

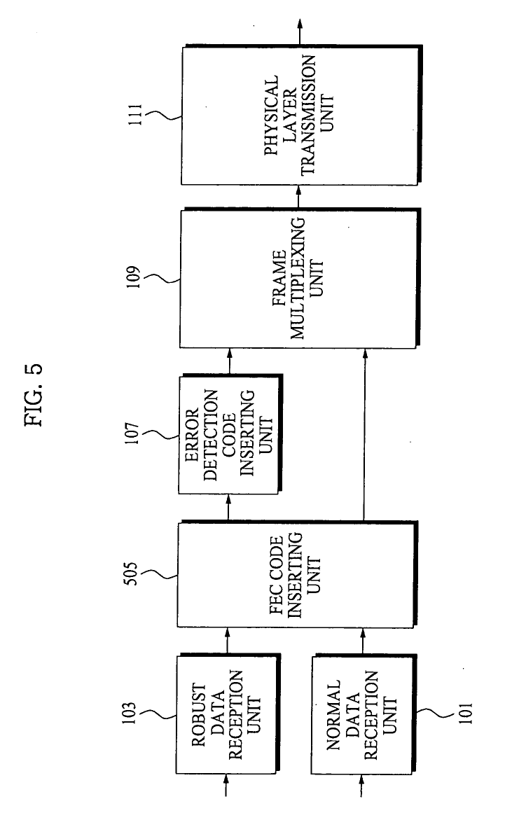

FIG. 1 is a diagram illustrating a configuration of an application layer transmission apparatus for FEC coding according to an embodiment of the present invention. FIG. 5 is a diagram illustrating another configuration of an application layer transmission apparatus for FEC coding according to an embodiment of the present invention.

Referring to FIG. 1, the application layer transmission apparatus includes a normal data reception unit 101, a robust data reception unit 103, a forward error correction (FEC) code inserting unit 105, an error detection code inserting unit 107, a frame multiplexing unit 109, and a physical layer transmission unit 111.

The robust data reception unit 103 receives robust data that is data to be coded being robust with respect to error, the robust data including cost data, charged data, and important data, and provides the received robust data to the FEC code inserting unit 105. In this instance, the robust data includes robust identification information used for identifying robust data.

The normal data reception unit 101 receives normal data that is not classified as robust data, and provides the received normal data to the frame multiplexing unit 109.

The FEC code inserting unit 105 inserts an FEC code for error correction to the received robust data, and outputs the robust data where the FEC code is inserted to the detection code inserting unit 107. Also, an FEC code inserting unit 505 of FIG. 5 may insert an FEC code of normal data or a parity bit of the normal data in addition to the FEC code of the robust data.

The error detection code inserting unit 107 inserts an error detection code for error detection, to the robust data where the FEC code is inserted. In this instance, the error detection code inserting unit 107 inserts the error detection code instead of a Moving Pictures Experts Group-transport stream (MPEG-TS) sync byte that is typically included in a TS packet, when the robust data where the FEC code is inserted is constituted by an MPEG-TS packet. Here, the MPEG-TS sync byte is information used for determining whether synchronization is achieved. An MPEG-TS packet is constituted by 188 bytes where the first four bytes are header information and the remaining 184 bytes are data information. The first byte of the header information is a sync byte having a value of ‘0x47’ and is utilized when a reception unit identifies a beginning of a new MPEG-TS 188 byte. Accordingly, the first byte of the header of the MPEG-TS packet is referred to as the sync byte.

The frame multiplexing unit 109 receives the robust data from the error detection code inserting unit 107, the robust data including the FEC code and the error detection code, receives the normal data from the normal data reception unit 101, and multiplexes the received robust data and the normal data to output to the physical layer transmission unit 111.

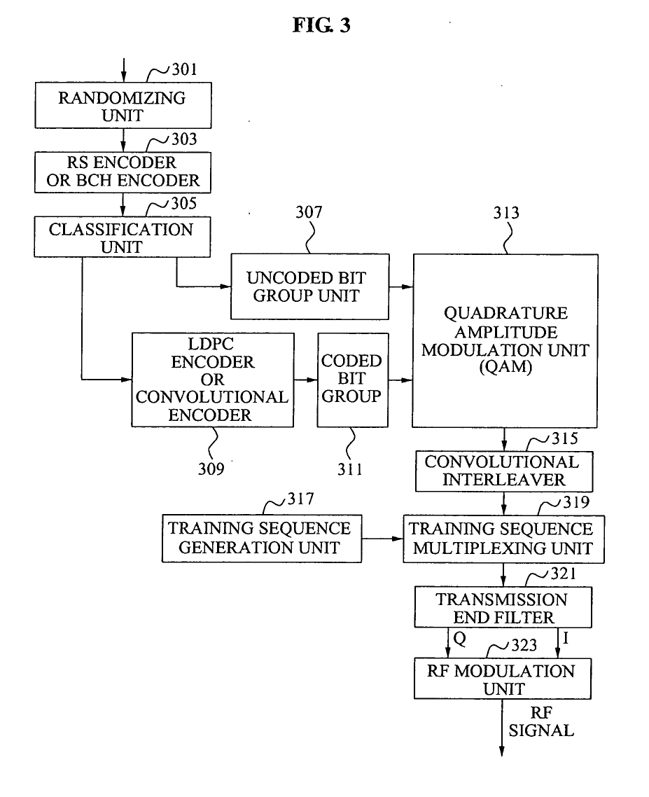

The physical layer transmission unit 111 performs adaptable/variable type modulation of the received multiplexed data stream to output a generated RF signal. Detailed description for the physical layer transmission unit 111 will be disclosed with reference to FIG. 3.

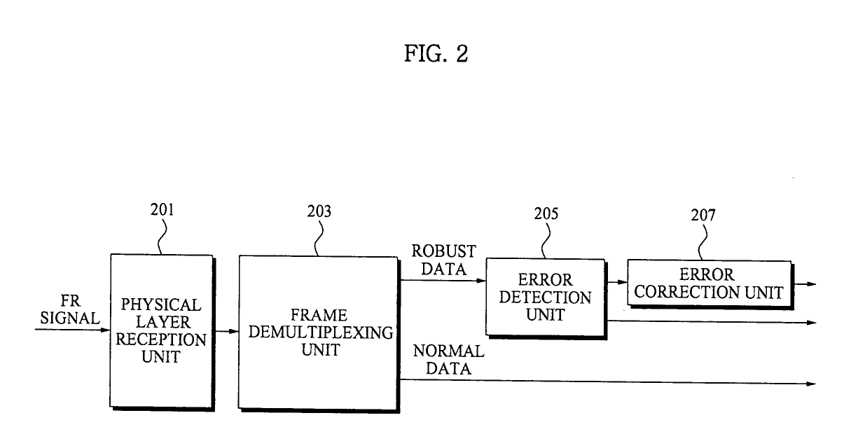

FIG. 2 is a diagram illustrating a configuration of an application layer reception apparatus for FEC decoding according to an embodiment of the present invention.

Referring to FIG. 2, the application layer reception apparatus includes a physical layer reception unit 201, a frame demultiplexing unit 203, an error detection unit 205, and an error correction unit 207.

The physical layer reception unit 201 receives an RF signal, performs adaptable/variable demodulation of the received RF signal, and outputs a data stream to the frame demultiplexing unit 203.

When receiving the data stream from the physical layer reception unit 201, the frame demultiplexing unit 203 classifies the received data stream into normal data and robust data using robust data identification information of the received data stream. Next, the frame demultiplexing unit 203 outputs the normal data as is and outputs the robust data to the error detection unit 205.

When receiving the robust data from the frame demultiplexing unit 203, the error detection unit 205 uses an error detection code included in the robust data to detect whether an error exists. When an error is not detected, the robust data is outputted as is, and when an error is detected, the error detection unit 205 outputs the robust data to the error correction unit 207. In this instance, according to the present invention, when the robust data is constituted by an MPEG-TS packet, the error detection code is included in a header of the MPEG-TS packet including an MPEG-TS sync byte.

Also, when the error detection unit 205 identifies that either an FEC code or a parity bit, the FEC code and the parity bit being of the normal data and the normal data being received together with the robust data, is added to the robust data, and the error detection unit 205 either outputs data indicating existence/absence of an error in the normal data or provides the FEC code of the normal data to the error correction unit 207 to correct the error, using either the added FEC code of the normal data or the parity bit of the normal data.

When the error is detected as a result of the detection of the error detection unit 205, the error correction unit 207 checks the FEC code included in the robust data, and outputs the robust data after correcting the error when error correction is possible.

FIG. 3 is a diagram illustrating a configuration of a physical layer transmission apparatus including an adaptable/variable type modulation apparatus according to an embodiment of the present invention.

FIG. 3 illustrates a detailed configuration of the physical layer transmission apparatus 111 of FIG. 1, the physical layer transmission apparatus 111 including a randomizing unit 301, a Reed-Solomon (RS) or Bose-Chaudhuri-Hocquenghen (BCH) encoder 303, a classification unit 305, an uncoded bit group unit 307, a low density parity check (LDPC) encoder or convolutional encoder 309, coded bit group unit 311, a quadrature amplitude modulation unit (QAM) 313, a convolutional interleaver 315, a training sequence symbol generation unit 317, a training sequence multiplexing unit 319, a transmission end filter 321, and a radio frequency (RF) modulation unit 323.

When receiving an input signal, the randomizing unit 301 randomizes the received input signal using a pseudo random binary sequence (PRBS) equation and outputs the randomized signal to the RS or BCH encoder 303. The RS or BCH encoder 303 is a device for inserting an error correction code, and is able to provide an RS code scheme or BCH code scheme. The error correction code is inserted to recover from an error occurring in a high signal to noise ratio (SNR) before performing LDPC coding.

The classification unit 305 receives an output of the RS or BCH encoder 303 and classifies the received output into either a bit stream to be LDPC-coded or a bit stream not to be LDPC-coded depending on a standard that is determined in advance with the physical layer reception unit 201. The uncoded bit group unit 307 groups the bit stream not to be LDPC-coded by a predetermined number of bits and outputs the uncoded bit groups to the QAM 313.

The LDPC encoder 309 performs LDPC-coding of the bit stream to be coded and outputs the coded bit stream to the coded bit group unit 311. In this instance, the LDPC encoder 309 may be replaced with the convolutional encoder 309. In a case of using the convolutional encoder 309, the convolutional encoder 309 performs convolutional coding of the bit stream to be coded and outputs the coded bit stream to the coded bit group unit 311.

The coded bit group unit 311 groups the coded bit streams by a predetermined number of bits and outputs the coded bit groups to the QAM 313. The QAM 313 selects a symbol coset using the coded bit groups, determines a symbol from the selected symbol coset using the uncoded bit groups, and outputs the selected symbol to the convolutional interleaver 315. The convolutional interleaver 315 performs convolutional interleaving of the symbol received from the QAM 313.

The training sequence symbol generation unit 317 outputs a predetermined training sequence symbol to the training multiplexing unit 319. The training multiplexing unit 319 outputs the convolutional interleaved symbol while the convolutional interleaved symbol is received, for channel equalization, and outputs the training sequence symbol to the transmission end filter 321 when the convolutional interleaved symbol is no longer received. Also, the training symbol generation unit 317 determines whether to insert the training sequence by signaling with the physical layer reception apparatus, and transmits the training sequence variably depending on the determination.

The transmission end filter 321 is a filter used for eliminating a transmission bandwidth limitation and intersymbol interference (ISI), and filters outputs of the training stream multiplexing unit 319 to provide the filtered outputs to the RF modulation unit 323. The transmission filter 321 may perform root raised cosine filtering. The RF modulation unit 323 performs RF modulation of the signal received from the transmission end filter 321, and outputs the RF modulated signal.

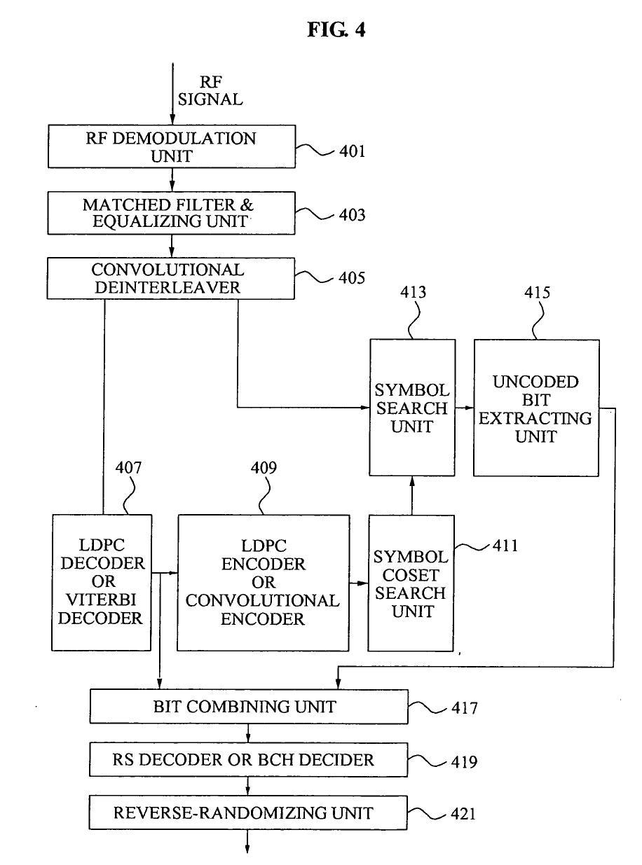

FIG. 4 is a diagram illustrating a configuration of a physical layer reception apparatus including an adaptable/variable type demodulation apparatus according to an embodiment of the present invention.

FIG. 4 illustrates a detailed configuration of the physical layer reception apparatus 201 of FIG. 2, the physical layer reception apparatus 201 including an RF demodulation unit 401, a matched filter & equalizing unit 403, a convolutional deinterleaver 405, an LDPC decoder or Viterbi decoder 407, an LDPC encoder or a convolutional encoder 409, a symbol coset search unit 413, a symbol search unit 415, an uncoded bit extracting unit 415, a bit combining unit 417, an RS or BCH decoder 419, and a reverse-randomizing unit 421.

The RF demodulation unit 401 performs demodulation of an RF signal and outputs the demodulated RF signal to the matched filter & equalizing unit 403. The matched filter & equalizing unit 403 performs filtering of the demodulated signal, performs channel-equalizing of the filtered signal based on a predetermined training sequence, and outputs the channel-equalized signal to the convolutional deinterleaver 405.

The equalizing unit of the matched filter & equalizing unit 403 checks whether to insert the training sequence by signaling with a physical layer transmission apparatus, and, depending on the result of the determination, variably receives the training sequence. That is, the equalizing unit performs channel-equalizing using the training sequence only when the training sequence is inserted.

The convolutional interleaver 405 outputs a soft decision uncoded bit group and a soft decision coded bit group by convolutional deinterleaving a received channel-equalized signal. The convolutional deinterleaver 405 generates an output bit of a predetermined location to be outputted, to the LDPC decoder 407, as the soft decision uncoded bit group and an output bit of a remaining location to be outputted, to the symbol search unit 415, as the soft decision coded bit group.

When receiving the soft decision coded bit group from the convolutional deinterleaver 405, the LDPC decoder 407 performs LDPC-decoding of the soft decision coded bit group, and outputs the decoded bit group to the LDPC encoder 409 and to the bit combining unit 417. The LDPC encoder 409 performs LDPC-coding of the decoded bit group received from the LDPC decoder 407 and outputs, to the symbol coset search unit 413, the coded bit group of which error is corrected.

Also, in this instance, the LDPC decoder 407 may be replaced with a Viterbi decoder 407. In a case of using the Viterbi decoder 407, the Viterbi decoder 407 performs Viterbi decoding of the soft decision coded bit group and outputs the decoded bit group to the bit combining unit 417 and to the convolutional encoder 409. In this instance, the convolutional encoder 409 may be used as a substitution for the LDPC encoder 409.

Also, the LDPC decoder 407 is able to perform error detection and error correction by a bit unit when performing decoding, and also able to obtain error information in a packet unit. Accordingly, the LDPC decoder 407 performs error detection by a packet unit and provides the error detection information to the application layer reception apparatus when the error detection inserting unit 107 is not applicable in the application layer transmission apparatus. The error detection information is included in the first four bytes of the 188 bytes of a header of an MPEG-TS packet.

Subsequently, the convolutional encoder 409 performs convolutional encoding of the decoded bit group received from the Viterbi decoder 407, and outputs the convolutional encoded group as a coded bit group of which error is corrected for the symbol coset search unit 411.

The symbol coset search unit 411 selects a symbol coset using the coded bit group received from the LDPC encoder 409 and outputs the selected symbol coset to the symbol search unit 413. The symbol search unit 413 selects a symbol from the selected symbol coset received from the symbol coset search unit 411, using the soft decision uncoded bit group received from the convolutional deinterleaver 405, and outputs the selected symbol to the uncoded bit extracting unit 415.

The uncoded bit extracting unit 415 extracts the uncoded bit group from the selected symbol received from the symbol search unit 413 and outputs the extracted uncoded bit group to the bit combining unit 417. The bit combining unit 417 combines the uncoded bit group received from the uncoded bit extracting unit 415 and the decoded bit group received from the LDPC decoder 407 to generate a bit stream, and outputs the generated bit stream to the RS or BCH decoder 419.

The RS or BCH decoder 419 performs RS decoding or BCH decoding of the received bit stream according to a used code scheme, and outputs the decoded bit stream to the reverse-randomizing unit 421.

Also, the RS or BCH decoder 419 is able to perform error detection and error correction by a bit unit when performing decoding, and is able to obtain error detection information in a packet unit.

Accordingly, the RS or BCH decoder 419 performs error detection in a packet unit and provides the error detection information to the application layer reception apparatus when the error detection inserting unit 107 is not suitable for the physical layer transmission apparatus. The error detection information is included in the first four bytes of 188 bytes, namely a header of an MPEG-TS packet.

Also, example of devices performing error detection by a packet unit may include all decoders where FEC is suitable, in addition to the LDPC decoder 407 and the RS or BCH decoder 419.

When receiving the decoded bit stream from the RS or BCH decoder 419, the reverse-randomizing unit 421 performs reverse-randomizing of the received decoded bit stream. The reverse-randomizing unit 421 restores the randomized signal to an original signal, the restoring being a reverse operation of the randomizing performed in the randomizing unit of FIG. 301.

Although embodiments of the present invention have been shown and described the physical layer and application layer transmission/reception apparatus in a digital transmission/reception system with respect to FIGS. 1 through 4, the present invention is also applicable to a territorial wave transmission/reception system, a satellite signal transmission/reception system, and an IPTV system, in addition to the digital transmission/reception system.

Although a few embodiments of the present invention have been shown and described, the present invention is not limited to the described embodiments. Instead, it would be appreciated by those skilled in the art that changes may be made to these embodiments without departing from the principles and spirit of the invention, the scope of which is defined by the claims and their equivalents.

1. A physical layer transmission apparatus for adaptable/variable type modulation, the apparatus comprising:
a classification unit to classify a bit stream into a bit stream to be low density parity check (LDPC)-coded and a bit stream not to be LDPC-coded according to a predetermined scheme, when receiving the bit stream;
an uncoded bit group unit to group the bit stream not to be LDPC-coded by a predetermined number of bits to output the uncoded bit groups;
an LDPC encoder to perform LDPC-coding of the bit stream to be LDPC-coded to output the coded bit stream;
a coded bit group unit to group the coded bit stream by the predetermined number of bits to output the coded bit groups;
a quadrature amplitude modulation (QAM) unit to select a symbol coset by using the coded bit group and to determine a symbol from the selected symbol coset by using the uncoded bit group; and
a convolutional interleaver to perform convolutional interleaving of the symbol determined by the quadrature amplitude modulation unit.

2. The apparatus of claim 1, further comprising:
a training sequence generation unit to output a predetermined training sequence symbol; and
a training sequence multiplexing unit to output the convolutional interleaved symbol while the convolutional interleaved symbol is received, and to output the training sequence symbol when the convolutional interleaved symbol is no longer received.

3. The apparatus of claim 1, further comprising an error correction code inserting unit to insert an error correction code for error correction,
wherein the bit stream that the classification unit receives has an insertion of the error correction code through the error correction code inserting unit.

4. The apparatus of claim 1, wherein the LDPC encoder is replaceable with the convolutional encoder that performs convolutional coding of the bit stream to be coded to output the coded bit stream.

5. A physical layer reception apparatus for adaptable/variable type demodulation, the apparatus comprising:
a convolutional deinterleaver to output a soft decision uncoded bit group and a soft decision coded bit group by convolutional deinterleaving a received signal;
an LDPC decoder to perform LDPC-decoding of the soft decision coded bit group to output a decoded bit group;
an LDPC encoder to perform LDPC-coding of the decoded bit group to output a coded bit group;
a symbol coset search unit to select a symbol coset by using the coded bit group;
a symbol search unit to select a symbol from the selected symbol coset that the symbol coset search unit selects, by using the soft decision uncoded bit group;
an uncoded bit extracting unit to extract an uncoded bit group from the symbol selected through the symbol search unit; and
a bit combining unit to combine the decoded bit group and the uncoded bit group to generate a bit stream.

6. The apparatus of claim 5, further comprising an equalizing unit to perform channel-equalizing of the received signal based on a predetermined training sequence and to transmit the channel-equalized signal to the convolutional deinterleaver.

7. The apparatus of claim 5, further comprising an error correction unit to correct an error by checking an error correction code included in the bit stream.

8. The apparatus of claim 5, wherein the LDPC decoder is replaceable with a Viterbi decoder that decodes the soft decision coded bit group to output a decoded bit group, and the LDPC encoder is replaceable with a convolutional encoder that performs convolutional coding of the decoded bit group to output the coded bit group.

9. The apparatus of claim 5, further comprising a decoder to receive the bit stream, to decode the received bit stream, and to obtain error detection information in a packet unit.

10. An application layer transmission apparatus, the apparatus comprising:
a forward error correction (FEC) code inserting unit to insert, to received robust data, an FEC code for error correction;
an error detection code inserting unit to insert, to the robust data where the FEC code is inserted, an error detection code to detect whether the error exists; and
a frame multiplexing unit to receive and multiplex normal data and the robust data where the FEC code and the error detection code are inserted and to output the multiplexed data to a physical layer.

11. The apparatus of claim 10, wherein the robust data is data to be coded being robust with respect to the error, the robust data including cost data, charged data, and important data.

12. The apparatus of claim 10, wherein the error detection code inserting unit constructs a transport stream (TS) packet by inserting the error detection code instead of a Moving Pictures Experts Group-TS (MPEG-TS) sync byte when the robust data where the FEC code is inserted through the FEC code inserting unit is constituted by the TS packet.

13. The apparatus of claim 10, wherein the FEC code inserting unit inserts, to the normal data, the FEC code for error correction, and the frame multiplexing unit receives and multiplexes the robust data where the FEC code and the error detection code are inserted and the normal data where the FEC code is inserted, and outputs the multiplexed data to the physical layer.

14. An application layer reception apparatus the apparatus comprising:
a frame demultiplexing unit to output data by classifying a normal data and robust data when receiving a data stream from a physical layer;
an error detecting unit to detect whether an error exists by checking an error detection code included in the robust data; and
an error correction unit to correct an error by checking an FEC code included in the robust data, when the error is detected by the error detecting unit.

15. The apparatus of claim 14, wherein the robust data is data to be coded being robust with respect to the error, the robust data including cost data, charged data, and important data.

16. The apparatus of claim 14, wherein the error detection unit detects the error by using the error detection code included in a section where an MPEG-TS sync byte is included when the robust data is constituted by a TS packet.
